(19) United States
(12) Patent Application Publication
(10) Pub. No.: US 2016/0109796 A1
(43) Pub. Date: Apr. 21, 2016

(54) OPTICAL MASK

(71) Applicant: Samsung Display Co., Ltd., Yongin-city (KR)

(72) Inventor: Ji Young CHOUNG, Hwaseong-si (KR)

(21) Appl. No.: 14/643,477

(22) Filed: Mar. 10, 2015

(30) Foreign Application Priority Data
Oct. 20, 2014 (KR) 10-2014-0141816

(51) Int. Cl. G03F 1/38

(52) U.S. Cl. CPC G03F 1/38

(57) ABSTRACT

Embodiments of an optical mask include a base substrate having one surface and an opposed other surface; a reflection pattern layer formed on the one surface of the base substrate, the reflection pattern layer having one surface and an opposed other surface and including a cut portion which light radiated from the other surface of the base substrate penetrates and a reflection unit reflecting the light; and a photothermal conversion pattern layer in a region overlapped with the cut portion. The photothermal conversion pattern layer is divided into a first region having high light absorptance and a second region having lower light absorptance than the first region. The different regions of the photothermal conversion pattern layer absorb incident light and convert the absorbed light into heat to sublimate a transfer material at different rates. Differential optical absorptance is achieved with an offset interference, wherein the first region has a structure of a first metal layer, an oxide layer, and a second metal layer, and the second region uses fewer of these layers.

### CROSS-REFERENCE TO RELATED APPLICATION

This application claims priority from Korean Patent Application No. 10-2014-0141816, filed on Oct. 20, 2014, in the Korean Intellectual Property Office, and all the benefits accruing therefrom under 35 U.S.C. §119, the contents of which in its entirety are herein incorporated by reference.

### BACKGROUND

1. Field

Exemplary embodiments relate to an optical mask, and more particularly, to an optical mask including a photothermal conversion pattern layer having differential optical absorptance.

2. Discussion of the Background

In general, an organic light emitting diode includes an anode electrode and a cathode electrode, and organic layers interposed between the anode electrode and the cathode electrode. The organic layers at least include an emission layer and may further include a hole injection layer, a hole transport layer, an electron transport layer, and an electron injection layer. Organic light emitting diodes can be divided into high-molecular organic light emitting diode types and low-molecular organic light emitting diode types according to the organic layer, in particular, a material constituting the emission layer.

In the organic light emitting diode, the emission layer needs to be patterned in order to implement a full-color organic light emitting diode, and a method for patterning the emission layer includes using a fine pattern mask in the case of the low-molecular organic light emitting diode and ink jet printing or laser induced thermal imaging (hereinafter, referred to as LITI) in the case of the high-molecular organic light emitting diode.

Among them, LITI has an advantage that the organic layer can be finely patterned and an advantage that the ink-jet printing is a wet process, while LITI is a dry process.

A method for forming a pattern of a high-molecular organic layer by the LITI process requires at least a light source, an organic light emitting diode substrate, that is, a diode substrate (alternatively, referred to as a transferred substrate), and a transfer substrate, and the transfer substrate includes a base film, a photothermal conversion layer, and a material layer formed by the organic layer.

Patterning on the diode substrate of the organic layer formed on the transfer substrate is performed while light emitted from the light source is absorbed by the photothermal conversion layer of the transfer substrate to be converted into thermal energy, and the organic layer constituting the material layer is transferred onto the diode substrate by the thermal energy.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide an optical mask including a photothermal conversion layer having differential optical absorptance.

Additional aspects will be set forth in the detailed description which follows, and, in part, will be apparent from the disclosure, or may be learned by practice of the inventive concept.

The objects of the present invention are not limited to the aforementioned technical objects, and other technical objects, which are not mentioned above, will be apparent to those skilled in the art from the following description.

An optical mask according to an exemplary embodiment comprises a base substrate; a reflection pattern layer; and a photothermal conversion pattern layer. The reflection pattern layer includes a cut portion which light radiated from the other surface of the base substrate penetrates and a reflection unit reflecting the light, which are formed on one surface of the base substrate. The photothermal conversion pattern layer is divided into a first region having high light absorptance and a second region having lower light absorptance than the first region in a region overlapped with the cut portion. The photothermal conversion pattern layer absorbs incident light and converts the absorbed light into heat. A step is formed on a boundary between the first region and the second region. The first region has a lamination structure of a first metal layer, an oxide layer, and a second metal layer.

An optical mask according to another exemplary embodiment comprises a base substrate; a reflection pattern layer including a cut portion which light radiated from the other surface of the base substrate penetrates and a reflection unit reflecting the light, which are formed on one surface of the base substrate; and a photothermal conversion pattern layer divided into a first region having high light absorptance and a second region having lower light absorptance than the first region in a region overlapped with the cut portion, and absorbing incident light and converting the incident light into heat, the first region and the second region having light absorptance of at least 40% or more.

When a material layer is transferred to a transferred substrate by using an optical mask, material layers having different thicknesses can be simultaneously transferred by one process.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic cross-sectional view of an optical mask according to a first embodiment of the present invention.

FIGS. 2 through 8 are cross-sectional views schematically illustrating a manufacturing process of the optical mask of FIG. 1.

FIG. 9 is a cross-sectional view schematically illustrating a process of transferring a material layer onto a transferred substrate by using the optical mask of FIG. 1.

FIG. 10 is a cross-sectional view schematically illustrating a modified example of the optical mask of FIG. 1 according to the present invention.

FIG. 11 is a cross-sectional view schematically illustrating the process of transferring the material layer onto the transferred substrate by using the optical mask of FIG. 10.

FIG. 12 is a schematic cross-sectional view of an optical mask according to a second embodiment of the present invention.

FIG. 13 is a schematic cross-sectional view of an optical mask according to a third embodiment of the present invention.

FIG. 14 is a schematic cross-sectional view of an optical mask according to a fourth embodiment of the present invention.

FIG. 15 is a schematic cross-sectional view of an optical mask according to a fifth embodiment of the present invention.

FIG. 16 is a schematic cross-sectional view of an optical mask according to a sixth embodiment of the present invention.

FIG. 17 is a schematic cross-sectional view of an optical mask according to a seventh embodiment of the present invention.

FIG. 18 is a schematic cross-sectional view of an optical mask according to an eighth embodiment of the present invention.

FIG. 19 is a schematic cross-sectional view of an optical mask according to a ninth embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

Hereinafter, embodiments of the present invention will be described with reference to the accompanying drawings.

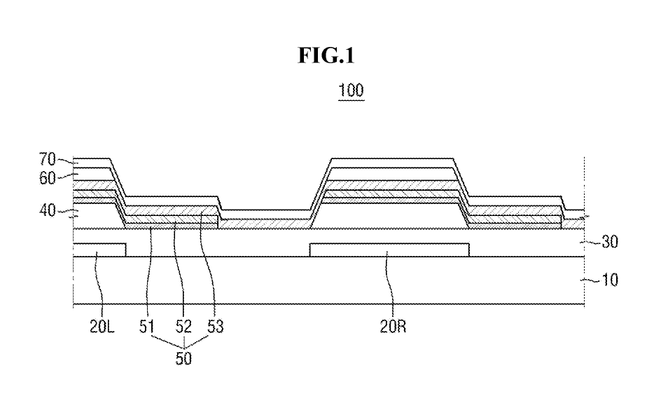

FIG. 1 is a schematic cross-sectional view of an optical mask 100 according to a first embodiment of the present invention.

Referring to FIG. 1, the optical mask 100 according to the first embodiment of the present invention may include a base substrate 10, reflection units 20L and 20R that are spaced apart from each other, a buffer layer 30 covering one surface of the base substrate 10, which is exposed between the reflection units 20L and 20R and one surface of each of the reflection units 20L and 20R, a taper layer 40 formed in a region overlapped with the reflection units 20L and 20R on one surface of the buffer layer 30, a photothermal conversion pattern layer 50 formed on one surface of the buffer layer 30, which is exposed between one surface of the taper layer 40 and another surface of the adjacent taper layer 40, a bank layer 60 in a region overlapped with the taper layer 40 on the photothermal conversion pattern layer 50, and a material layer 70 formed on one surface of the bank layer 60 and one surface of the photothermal conversion pattern layer 50.

The base substrate 10 may be a light transmissive substrate which light emitted from a light source may transmit. The light source may be a flash lamp, a tungsten halogen lamp, or a laser beam. The light source is disposed below the other surface of the base substrate 10. The base substrate 10 may be a flat plate type substrate.

If the base substrate 10 is a substrate having light transmittance, the base substrate 10 is not particularly limited, but may be a glass substrate, a quartz substrate, a synthetic resin substrate made of a transparent high-molecular material such as polyester, polyacryl, polyepoxy, polyethylene, polystyrene, polyethylene terephthalate, and the like.

A reflection pattern layer may be formed on one surface of the base substrate 10. The reflection pattern layer may be configured to include the reflection units 20L and 20R that are spaced apart from each other and a cut portion that exposes one surface of the base substrate 10 between the reflection units 20L and 20R.

The reflection units 20L and 20R may serve to reflect light radiated from the other surface of the base substrate 10. The reflection units 20L and 20R may be made of a material having high reflectance for the light emitted from the light source. The reflection units 20L and 20R may be flat plate type reflection layers.

As one example, the reflection units 20L and 20R may be made of gold, silver, platinum, copper, an alloy including aluminum, an alloy including silver, indium oxide, tin oxide, and the like.

The light emitting from the light source disposed on the other surface of the base substrate 10 may reach the photothermal conversion pattern layer 50 through the cut portion.

The buffer layer 30 serves to prevent thermal energy generated from the photothermal conversion pattern layer 50 from being diffused. The buffer layer 30 may be formed on one surface of each of the reflection units 20L and 20R and one surface of the base substrate 10 exposed through the cut portion. A top surface of the buffer layer 30 may have a flat surface.

The buffer layer 30 may be made of a material which is high in optical transmittance and low in thermal conductivity. In a relationship with the photothermal conversion pattern layer 50, the buffer layer 30 may be made of a material which is lower in thermal conductivity than the photothermal conversion pattern layer 50. As one example, the thermal conductivity of the buffer layer 30 may be 1.5 W/m K or less.

The buffer layer 30 may be made of any one of titanium oxide, silicon oxide, silicon nitride oxide, zirconium oxide, silicon carbon, silicon oxide (SiOₓ), silicon nitride (SiNₓ), and organic polymer. However, the present invention is not limited thereto.

In a relationship with the photothermal conversion pattern layer 50, the buffer layer 30 may be relatively thicker than the photothermal conversion pattern layer 50.

The taper layer 40 may be interposed between the buffer layer 30 and the photothermal conversion pattern layer 50. Further, the taper layer 40 may be formed in a region overlapped with the reflection units 20L and 20R. An included angle between the other (i.e., a lower) surface of the taper layer 40 and the side of the taper layer 40 may be less than 90°. As one example, the other surface of the taper layer 40 contacts one surface of the buffer layer 30 and may have a trapezoidal shape in which an area of the other surface is relatively larger than that of one surface facing the other surface.

When the taper layer 40 is manufactured in the trapezoidal shape, the photothermal conversion layer 50 and the material layer 70 may also have a substantially trapezoidal shape in a region overlapped with the taper layer 40.

An inclined side of the taper layer 40 faces a predetermined region of the transferred substrate to which the material layer 70 is to be transferred. The inclined side of the taper layer 40 may allow the photothermal conversion pattern layer 50 to face the predetermined region of the transferred substrate and the material layer 70 formed on the photothermal conversion pattern layer 50 covering the inclined side of the taper layer 40 may be evaporated toward a transfer scheduled region of the transferred substrate by heat generated from the photothermal conversion pattern layer 50.

The taper layer 40 may be made of a material which is high in optical transmittance and low in thermal conductivity. As one example, the taper layer 40 may be made of any one of titanium oxide, silicon oxide, silicon nitride oxide, zirconium oxide, silicon carbon, silicon oxide (SiOₓ), silicon nitride (SiNₓ), and organic polymer. However, the present invention is not limited thereto.

The photothermal conversion pattern layer 50 serves to absorb light in infrared rays-visible ray regions and convert the absorbed light into the thermal energy. The photothermal conversion pattern layer 50 may be formed by using various methods. For example, the photothermal conversion pattern layer 50 may be formed by a sputtering method, an electronic beam deposition method, a vacuum deposition method, and the like.

The photothermal conversion pattern layer 50 may be formed on one surface of the buffer layer 30 and overlaps the cut portion formed between the reflection units 20L and 20R. The photothermal conversion pattern layer 50 may be divided into a first region having high light absorptance and a second region having low light absorptance in the region. That is, the first region may have higher light absorptance than the second region. Further, the second region may have lower light absorptance than the first region.

The first region and the second region may have light absorptance of at least 40% or more. A difference in light absorptance between the first region which is the high-absorptance region and the second region which is the low absorptance region may be in the range of 10 to 40%. When the difference in light absorptance between the first region which is the high-absorptance region and the second region which is the low-absorptance region is less than 10%, a difference in thermal energy generated from the first region and the second region may not be large and when the difference in light absorptance between the first region which is the high-absorptance region and the second region which is the low-absorptance region is more than 40%, the difference in thermal energy is too large, and as a result, an organic material may be selectively transferred in the first region and the second region.

As one example, the light absorptance of the first region may be in the range of 80 to 95% and the light absorptance of the second region may be in the range of 40 to 70%.

The first region may have a lamination structure of a first metal layer 51, an oxide layer 52, and a second metal layer 53 and the second region may have a single layer structure constituted by only the second metal layer 53.

The photothermal conversion layer 50 may have a step on a boundary of the first region and the second region due to a difference in lamination structure between the first region and the second region.

The first metal layer 51 may be made of a metallic material having high absorptance, such as molybdenum (Mo), chrome (Cr), titanium (Ti), tin (Sn), tungsten (W), or an alloy including the same.

The oxide layer 52 may be made of transparent metal oxides such as ITO, IZO, and the like.

The second metal layer 53 may be made of the metallic material having high absorptance, such as molybdenum (Mo), chrome (Cr), titanium (Ti), tin (Sn), tungsten (W), or an alloy including the same.

The first metal layer 51 may be thinner than the second metal layer 53. Further, the first metal layer 51 may be thinner than the oxide layer 52.

The thickness of the first metal layer 51 may be in the range of 4 nm to 15 nm.

The thickness of the oxide layer 53 may be in the range of 50 nm to 150 nm.

The thickness of the second metal layer 53 may be in the range of 100 nm to 200 nm.

The light emitting from the light source is reflected on the first metal layer 51 or penetrates the first metal layer 51. The light that transmits the first metal layer 51 is transferred to the oxide layer 52 and transferred to the second metal layer 53. Light reflected on the other surface of the second metal layer 53 causes offset interference in the oxide layer 52 and multiple layers having the lamination structure of the first metal layer 51, the oxide layer 52, and the second metal layer 53 may improve the light absorptance in the first region by using the offset interference effect.

Therefore, the first region has higher light absorptance than the second region having the single layer structure constituted by only the second metal layer 53.

The lamination structure of the first metal layer 51, the oxide layer 52, and the second metal layer 53 may be extended to cover the side and one (i.e., an upper) surface of the taper layer 40.

The bank layer 60 may be formed on the photothermal conversion pattern layer 50. The bank layer 60 may be formed in the region overlapping the taper layer 40. The bank layer 60 may be made of the material that is high in optical transmittance and low in thermal conductivity like the buffer layer 30.

The bank layer 60 may serve to prevent the material layer 70 from being diffused to a region other than a predetermined region of the transferred substrate to allow the material layer 70 to be concentratively transferred to only the predetermined region.

The bank layer 60 may be made of any one of titanium oxide, silicon oxide, silicon nitride oxide, zirconium oxide, silicon carbon, silicon oxide (SiOₓ), silicon nitride (SiNₓ), and organic polymer. However, the present invention is not limited thereto.

An included angle between the other (i.e., a lower) surface and the side of the bank layer 60, which contact one surface of the photothermal conversion pattern layer 50 may be less than 90°. As one example, the bank layer 60 may have the trapezoidal shape. The surface that contacts one surface of the photothermal conversion pattern layer 50 is relatively larger than that of one (i.e., upper) surface.

The material layer 70 may be formed on one surface of the photothermal conversion pattern layer 50 formed in the region overlapping the cut portion and one surface of the bank layer 60 formed in the region overlapping the reflection units 20L and 20R. The material layer 70 may have the step in the region overlapping the cut portion due to the step formed on the boundary between the first region and the second region of the photothermal conversion pattern layer 50.

As one example, the material layer 70 may be made of an organic material and in detail, an organic material included in an organic light emitting display. That is, the material layer 70 may be made of an organic material constituting an organic light emitting layer (EML), a hole injection layer (HIL), a hole transport layer (HTL), an electron injection layer (EIL), and an electron transport layer (ETL).

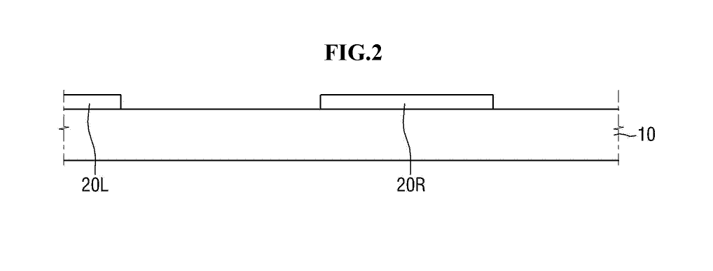

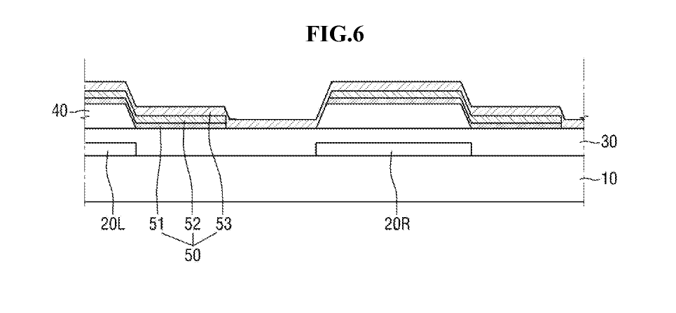

FIGS. 2 to 8 are cross-sectional views schematically illustrating a manufacturing process of the optical mask of FIG. 1.

FIG. 2 illustrates a step in which the reflection units 20L and 20R are formed on the base substrate 10.

The reflection units 20L and 20R may be formed on one surface of the base substrate 10 by fully depositing a reflection layer made of aluminum, gold, silver, platinum, copper, an alloy including aluminum, an alloy including silver, indium oxide, tin oxide, and the like and thereafter, removing a region corresponding to the cut portion.

The reflection units 20L and 20R which are spaced apart from each other may be formed on one surface of the base substrate 10 depositing a reflection layer made of aluminum, gold, silver, platinum, copper, an alloy including aluminum, an alloy including silver, indium oxide, tin oxide.

The reflection layer or the reflection units 20L and 20R may be formed by using various methods. For example, the reflection layer or the reflection units 20L and 20R may be formed by a sputtering method, an electronic beam deposition method, a vacuum deposition method, and the like.

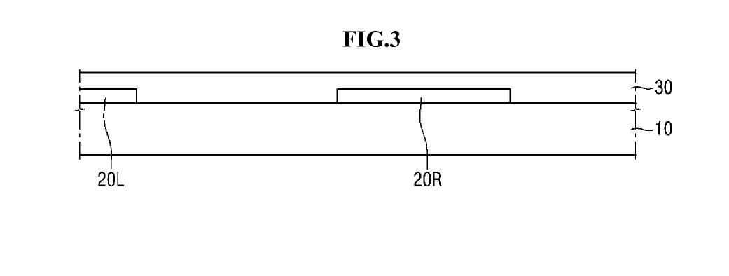

FIG. 3 illustrates a step in which the buffer layer 30 is formed on one surface of each of the reflection units 20L and 20R and one surface of the base substrate 10, which is exposed between the reflection units 20L and 20R.

The buffer layer 30 may be an overcoat layer having a thickness to cover one surface of each of the reflection units 20L and 20R and a flat layer of which one surface is flat.

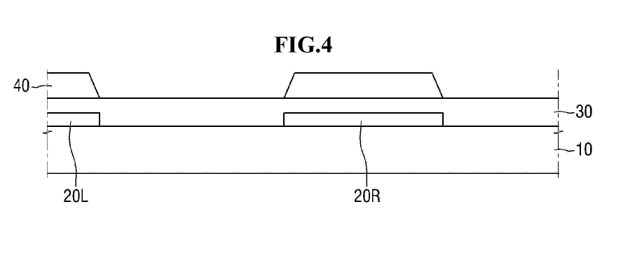

FIG. 4 illustrates a step in which the taper layer 40 is formed on one surface of the buffer layer 30.

The taper layer 40 may be selectively formed only in the region overlapping the reflection units 20L and 20R.

As one example, the taper layer 40 may be formed on one surface of the buffer layer 30 by fully depositing a taper layer film of titanium oxide, silicon oxide, silicon nitride oxide, zirconium oxide, silicon carbon, silicon oxide (SiOₓ), silicon nitride (SiNₓ), or organic polymer and thereafter, removing the region overlapped with the cut portion.

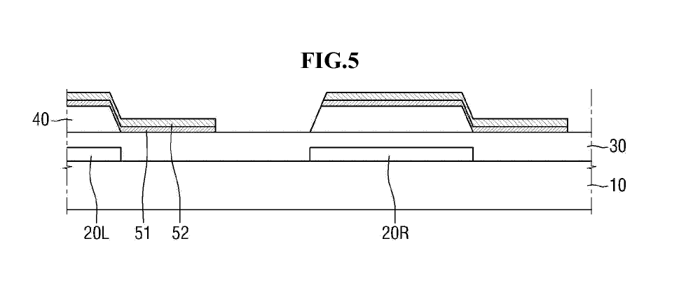

FIG. 5 illustrates a step in which the photothermal conversion pattern layer 50 is formed on one surface of the taper layer 40 and one surface of the buffer layer 30, which is exposed between the taper layers 40.

The first metal layer 51 may be formed on one surface of the taper layer 40 and one surface of the buffer layer 30, which is exposed between the taper 40 by using the sputtering method, the electronic beam deposition method, the vacuum deposition method, and the like.

The oxide layer 52 is formed on the first metal layer 51 to cover the entirety of one surface of the first metal layer 51.

For example, the first metal layer 51 and the oxide layer 52 of the second region are removed by using a photolithography etching method and the first metal layer 51 and the oxide layer 52 may be formed only in the first area.

The second metal layer 53 may be formed on one surface of each of the first metal layer 51 and the oxide layer 52, and one surface of the buffer layer 30 exposed between the first metal layer 51 and the taper layer 40 and the side of the taper layer 40. The second metal layer 53 may be formed by using the sputtering method, the electronic beam deposition method, the vacuum deposition method, and the like similarly to the first metal layer 51.

As a result, the multiple-layered photothermal conversion pattern layer 50 having the lamination structure of the first metal layer 51, the oxide layer 52, and the second metal layer 53 may be formed in the first region of the photothermal conversion pattern layer 50 overlapping the cut portion exposed between the reflection units 20L and 20R and the photothermal conversion pattern layer 50 having the single layer structure of only the second metal layer 53 may be formed in the second region.

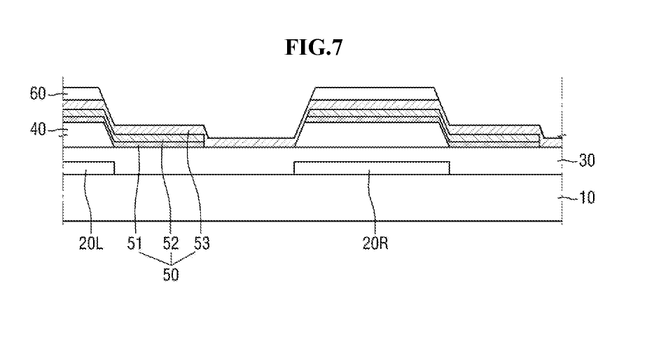

FIG. 7 schematically illustrates a step in which the bank layer 60 is selectively formed in only the region overlapping the taper layer 40 on the photothermal conversion pattern layer 50.

As one example, the taper layer 40 may be formed on one surface of the photothermal conversion pattern layer 50 by fully depositing a bank layer film of titanium oxide, silicon oxide, silicon nitride oxide, zirconium oxide, silicon carbon, silicon oxide (SiOₓ), silicon nitride (SiNₓ), or organic polymer and thereafter, removing the region overlapping the cut portion.

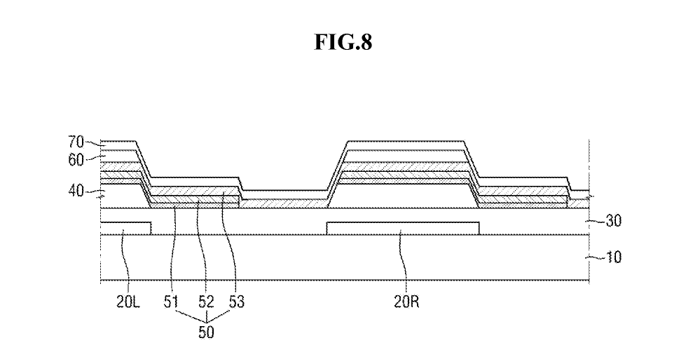

FIG. 8 schematically illustrates a step in which the material layer 70 is formed on one surface of the bank layer 60 and one surface of the photothermal conversion pattern layer 50.

A method for forming the material layer 70 is not particularly limited. As one example, the method for forming the material layer 70 may include a spin coat method, a spray coat method, an ink jet method, a deep coat method, a cast method, a die coat method, a roll coat method, a blade coat method, a bar coat method, a gravure coat method, or a printing method, which is a wet method. Further, the method for forming the material layer 70 may include the vacuum deposition method, the sputtering method, or the like, which is a wet method.

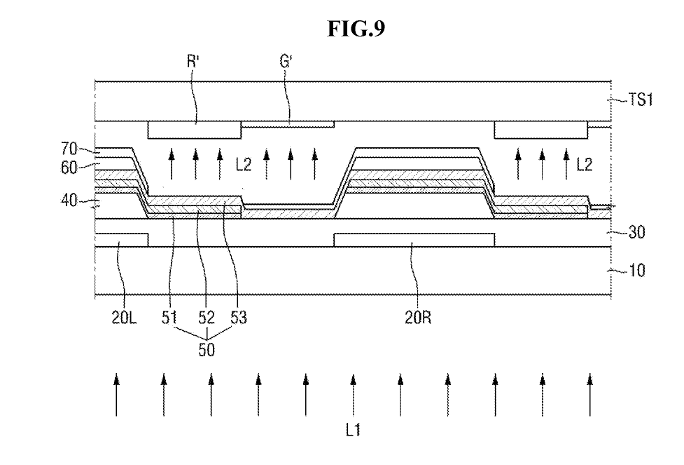

FIG. 9 is a cross-sectional view schematically illustrating a process of transferring the material layer 70 onto a transferred substrate TS1 by using the optical mask 100 of FIG. 1 according to the present invention.

Referring to FIG. 9, light L1 emitting from a light source disposed on the other surface of the optical mask 100 of FIG. 1 may be sequentially incident in the cut portion between the reflection units 20L and 20R, the buffer layer 30, and the photothermal conversion pattern layer 50.

The light incident in the photothermal conversion pattern layer 50 is converted into heat and the generated heat is transferred to the material layer 70. The material layer 70 may be selectively transferred onto the transferred substrate TS1 by the heat generated from the photothermal conversion pattern layer 50.

In the first region of the photothermal conversion pattern layer 50, the entirety of the material layer 70 is transferred onto the transferred substrate TS1 to form a first transfer layer R′, while in the second region having lower light absorptance than the first region, a part of the material layer 70 remains on one surface of the photothermal conversion pattern layer 50 and a residual part is transferred to the transferred substrate TS1 to form a second transfer layer G′. The reason is that the amounts of heat energy generated from the first region and the second region of the photothermal conversion pattern layer 50 are different from each other depending on a difference in light absorptance between the first region and the second region.

Some of the thermal energy generated by the light reaching the photothermal conversion pattern layer 50 through the cut portion formed between the reflection units 20L and 20R may be diffused to the photothermal conversion pattern layer 50 formed on the side of the taper layer 40 and although not illustrated, since the side of the taper layer 40 is inclined so that the photothermal conversion pattern layer 50 faces the first and second transfer layers R′ and G′, the thermal energy generated from the photothermal conversion pattern layer 50 formed on the side of the taper layer 40 may transfer the material layer 70 formed in the side of the taper layer 40 to the first and second transfer layers R′ and G′.

When the optical mask 100 according to the first embodiment of the present invention is used, the first and second transfer layers R′ and G′ having different thicknesses may be simultaneously formed by one process.

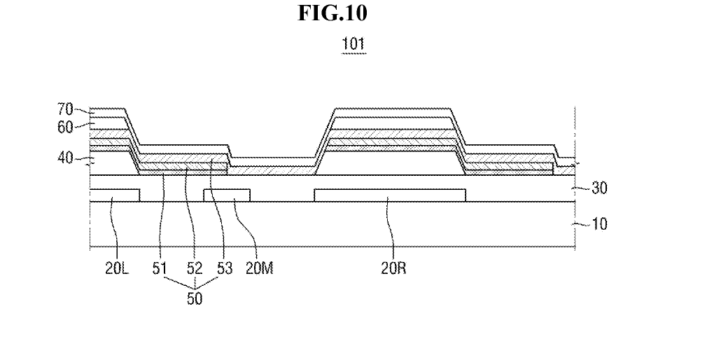

FIG. 10 is a cross-sectional view schematically illustrating a modified example of the optical mask of FIG. 1 according to the present invention.

The optical mask 101 of FIG. 10 is different from the optical mask 100 of FIG. 1 in that a reflection unit 20M is additionally formed between the reflection units 20L and 20R.

Referring to FIG. 10, it is illustrated that a part of the multiple layers having the lamination structure of the first metal layer 51, the oxide layer 52, and the second metal layer 53 is formed in a region overlapping the reflection unit 20M, but the present invention is not limited thereto and the multiple layers having the lamination structure of the first metal layer 51, the oxide layer 52, and the second metal layer 53 is formed in a region overlapping the cut portion formed between the reflection units 20L and 20R not to be overlapped with the reflection unit 20M.

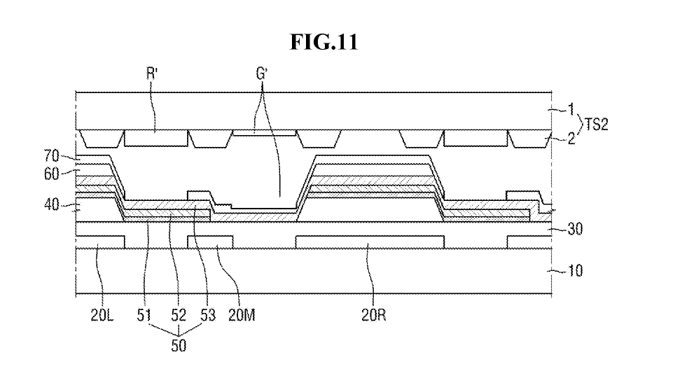

FIG. 11 is a cross-sectional view schematically illustrating a process of transferring the material layer 70 onto a transferred substrate TS2 by using the optical mask 101 of FIG. 10 according to the present invention.

The transferred substrate TS2 of FIG. 11 is different from the transferred substrate TS1 of FIG. 11 in that partitions 2 are disposed on the other surface of the substrate 1 to be spaced apart from each other. As one example, the transferred substrate TS2 may be a thin-film transistor substrate of the organic light emitting display and the partitions 2 may serve as a pixel defining layer that separates pixels.

Although not illustrated, pixel electrodes (not illustrated) are exposed among the partitions 2. The other surface of the pixel electrode (not illustrated) as a region onto which the organic material of the material layer 70 is transferred is disposed to overlap the cut portion. That is, the partitions 2 are disposed to overlap the reflection units 20L, 20M, and 20R.

Referring to FIG. 11, the material layer 70 formed in the region overlapping the reflection unit 20M is not transferred onto the transferred substrate TS2 and may remain on one surface of the photothermal conversion layer 50. The material layer 70 in the region overlapping the reflection unit 20M and the material layer 70 that remains in the second region have different thicknesses. That is, the material layer 70 that remains in the second region may have a smaller thickness than the material layer 70 in the region overlapped with the reflection unit 20M.

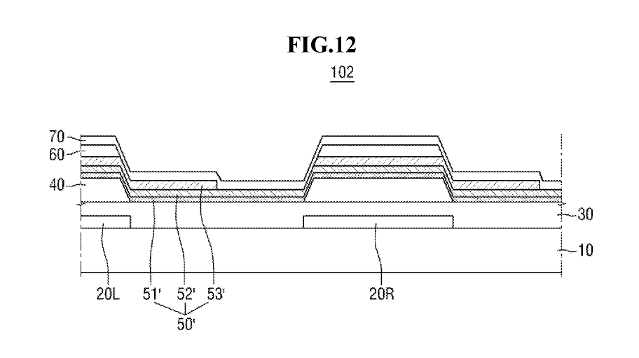

FIG. 12 is a schematic cross-sectional view of an optical mask 102 according to a second embodiment of the present invention.

The optical mask 102 of FIG. 12 is different from the optical mask 100 of FIG. 1 in that a first region of a photothermal conversion pattern layer 50′ has multiple layers having a lamination structure of a first metal layer 51′, an oxide layer 52′, and a second metal layer 53′ and a second region has dual layers having a lamination structure of the first metal layer 51′ and the oxide layer 52′.

The first metal layer 51′ is different from the first metal layer 51 of the optical mask of FIG. 1 in that the first metal layer 51 extends from the first region to the second region. However, the first metal layer 51′ is not limited to the structure in which the first metal layer 51′ extends from the first region to the second region and may be formed in each of the first region and the second region while being spaced apart from each other.

The oxide layer 52′ is different from the oxide layer 52 of the optical mask of FIG. 1 in that the oxide layer 52′ extends from the first region to the second region. However, the oxide layer 52′ is not limited to the structure in which the oxide layer 52′ extends from the first region to the second region and may be formed in each of the first region and the second region while being spaced apart from each other.

The second metal layer 53′ is different from the second metal layer 53 of the optical mask of FIG. 1 in that the second metal layer 53′ extends over the first region, but not over the second region.

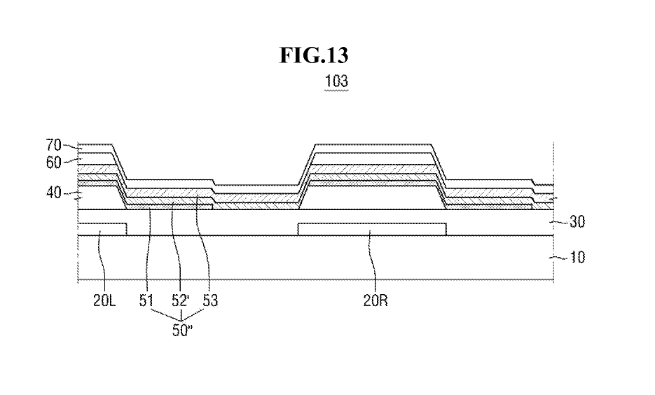

FIG. 13 is a schematic cross-sectional view of an optical mask 103 according to a third embodiment of the present invention.

The optical mask 103 of FIG. 13 is different from the optical mask 100 of FIG. 1 in that the first region is constituted by multiple layers having a lamination structure of the first metal layer 51, the oxide layer 52′, and the second metal layer 53 and the second region is constituted by dual layers having a lamination structure of the oxide layer 52′ and the second metal layer 53.

The oxide layer 52′ is different from the oxide layer 52 of the optical mask of FIG. 1 in that the oxide layer 52′ extends from the first region to the second region. However, the oxide layer 52′ is not limited to the structure in which the oxide layer 52′ extends from the first region to the second region and may be formed in each of the first region and the second region while being spaced apart from each other.

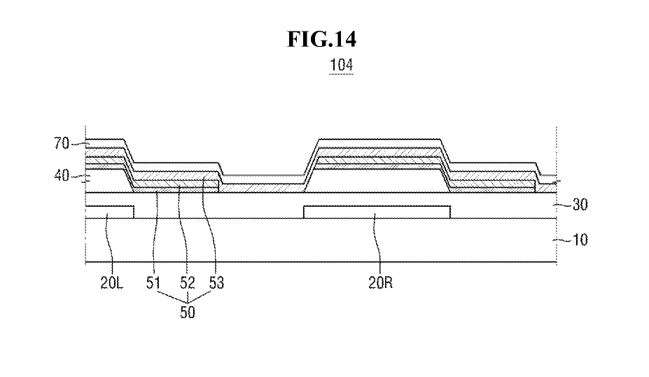

FIG. 14 is a schematic cross-sectional view of an optical mask 104 according to a fourth embodiment of the present invention.

The optical mask 104 of FIG. 14 is different from the optical mask 100 of FIG. 1 in that there is no bank layer 60 interposed between the photothermal conversion pattern layer 50 and the material layer 70.

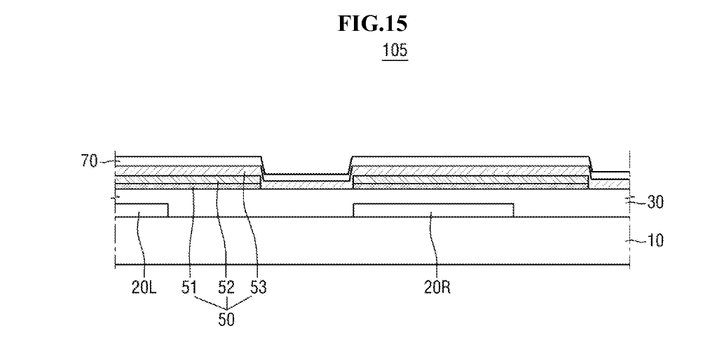

FIG. 15 is a schematic cross-sectional view of an optical mask 105 according to a fifth embodiment of the present invention.

The optical mask 105 of FIG. 15 is different from the optical mask 100 of FIG. 1 in that there is no bank layer 60 interposed between the photothermal conversion pattern layer 50 and the material layer 70 and there is no taper layer 40 interposed between the photothermal conversion pattern layer 50 and the buffer layer 30.

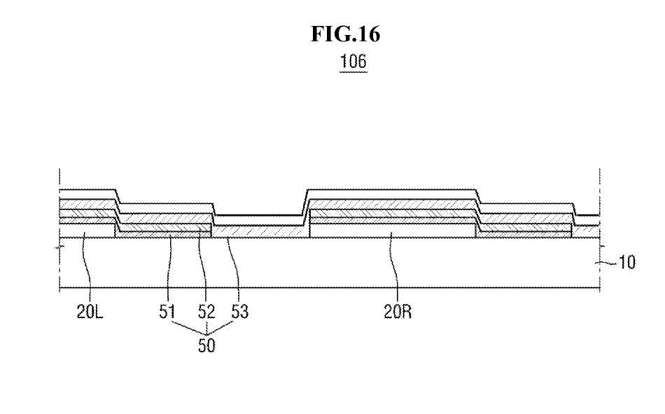

FIG. 16 is a schematic cross-sectional view of an optical mask 106 according to a sixth embodiment of the present invention.

The optical mask 106 of FIG. 16 is different from the optical mask 105 of FIG. 15 in that there is no buffer layer 30 interposed between the photothermal conversion pattern layer 50 and the base layer 10.

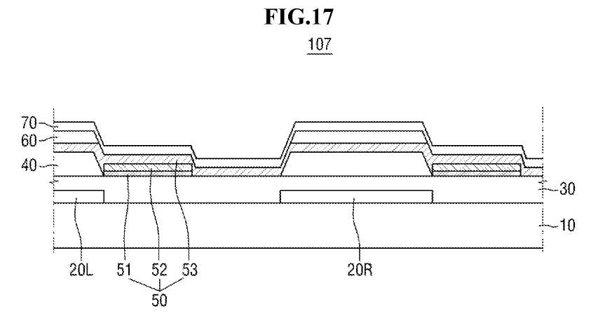

FIG. 17 is a schematic cross-sectional view of an optical mask 107 according to a seventh embodiment of the present invention.

The optical mask 107 of FIG. 17 is different from the optical mask 100 of FIG. 1 in that the multiple layers having the lamination structure of the first metal layer 51, the oxide layer 52, and the second metal layer 53 do not extend onto one surface of the taper layer 40.

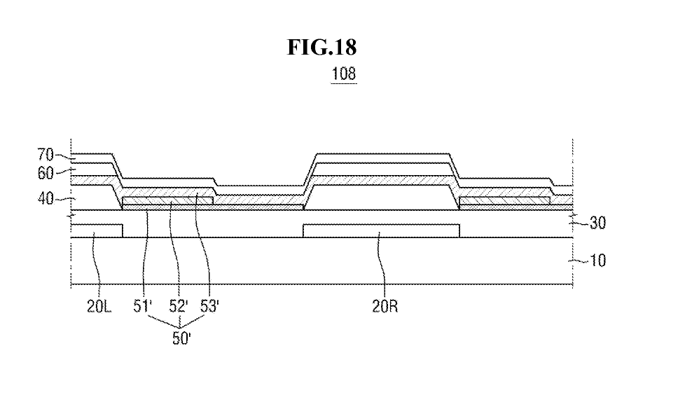

FIG. 18 is a schematic cross-sectional view of an optical mask 108 according to an eighth embodiment of the present invention.

The optical mask 108 of FIG. 18 is different from the optical mask 102 of FIG. 12 in that the multiple layers having the lamination structure of the first metal layer 51′, the oxide layer 52′, and the second metal layer 53′ do not extend onto one surface of the taper layer 40.

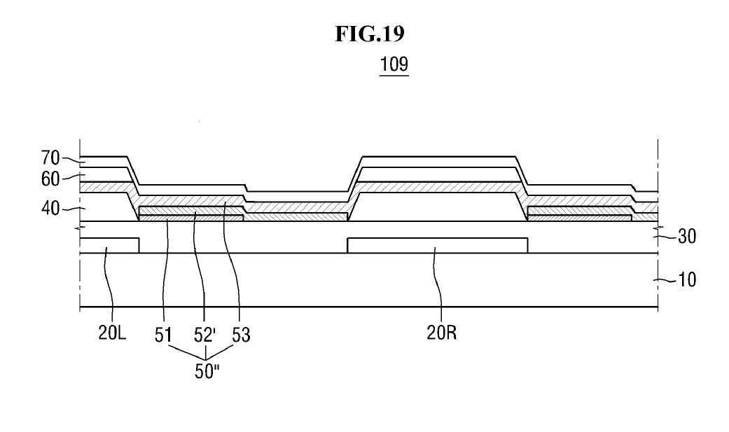

FIG. 19 is a schematic cross-sectional view of an optical mask 109 according to a ninth embodiment of the present invention.

The optical mask 109 of FIG. 19 is different from the optical mask 103 of FIG. 13 in that the multiple layers having the lamination structure of the first metal layer 51, the oxide layer 52′, and the second metal layer 53 do not extend onto one surface of the taper layer 40.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An optical mask, comprising:
a base substrate having one surface and an other surface opposing the one surface;
a reflection pattern layer formed on the one surface of the base substrate; and
a photothermal conversion pattern layer, wherein
the reflection pattern layer comprises:
a cut portion through which light radiated from the other surface of the base substrate penetrates; and
a reflection unit reflecting the light,
wherein the photothermal conversion pattern layer is formed in a region overlapping the cut portion and divided into a first region and a second region,
wherein the first region has higher light absorptance that the second region,
wherein the photothermal conversion pattern layer is configured to absorb incident light and convert the absorbed light into heat, and
wherein the first region comprises a lamination structure of a first metal layer, an oxide layer, and a second metal layer.

2. The optical mask of claim 1, wherein the second region has a single layer of the first metal layer.

3. The optical mask of claim 1, wherein the second region has a lamination structure of the first metal layer and the oxide layer.

4. The optical mask of claim 1, wherein the second region has a lamination structure of the oxide layer and the second metal layer.

5. The optical mask of claim 1, wherein the first region and the second region have light absorptance of at least 40% or more.

6. The optical mask of claim 5, wherein the light absorptance of the first region is in the range of 80 to 95% and the light absorptance of the second region is in the range of 40 to 70%.

7. The optical mask of claim 1, wherein the first metal layer is thinner than the second metal layer.

8. The optical mask of claim 7, wherein:
a thickness of the first metal layer is in the range of 4 to 15 nm, and
a thickness of the second metal layer is in the range of 100 to 200 nm.

9. The optical mask of claim 1, wherein the first metal layer is thinner than the oxide layer.

10. The optical mask of claim 9, wherein:
a thickness of the first metal layer is in the range of 4 to 15 nm, and
a thickness of the oxide layer is in the range of 50 to 150 nm.

11. The optical mask of claim 1, further comprising:
a buffer layer interposed between the base substrate and the photothermal conversion pattern layer and covering the reflection pattern layer.

12. The optical mask of claim 11, further comprising:
a taper layer comprising one surface, an other surface opposing the one surface, and a side surface disposed therebetween, the taper layer interposed between the buffer layer and the photothermal conversion pattern layer and formed in a region overlapping the reflection pattern layer,
wherein an included angle between the other surface and the side surface of the taper layer is less than 90°.

13. The optical mask of claim 12, further comprising:
a bank layer comprising one surface, an other surface opposing to the one surface, and a side surface disposed therebetween, the bank layer formed in a region overlapping the taper layer on the photothermal conversion pattern layer,
wherein an included angle between the other surface and the side surface of the bank layer is less than 90°.

14. The optical mask of claim 1, further comprising:
a material layer formed on the photothermal conversion pattern layer and sublimated by heat generated from the photothermal conversion pattern layer.

15. The optical mask of claim 13, further comprising:
a material layer formed on the photothermal conversion pattern layer and the bank layer and sublimated by the heat generated from the photothermal conversion pattern layer.

16. An optical mask, comprising:
a base substrate comprising one surface and an opposed other surface;
a reflection pattern layer formed on the one surface of the base substrate, the reflection pattern layer comprising a cut portion which light radiated from the other surface of the base substrate penetrates and a reflection unit reflecting the light; and
a photothermal conversion pattern layer in a region overlapping the cut portion, the photothermal conversion pattern layer divided into a first region having high light absorptance and a second region having lower light absorptance than the first region, and absorbing incident light and converting the incident light into heat,
wherein the first region and the second region have a light absorptance of at least 40% or more.

17. The optical mask of claim 16, wherein:
the first region has a lamination structure comprising a first metal layer, an oxide layer, and a second metal layer, and
the second region has a single layer of the first metal layer.

18. The optical mask of claim 16, wherein:
the first region has a lamination structure comprising a first metal layer, an oxide layer, and a second metal layer, and
the second region has a lamination structure consisting of the first metal layer and the oxide layer.

19. The optical mask of claim 16, wherein:
the first region has a lamination structure comprising a first metal layer, an oxide layer, and a second metal layer, and
the second region has a lamination structure consisting of the oxide layer and the second metal layer.
